(19) United States
(12) Patent Application Publication
(10) Pub. No.: US 2024/0347682 A1
(43) Pub. Date: Oct. 17, 2024

(54) SEMICONDUCTOR DEVICE AND ELECTRONIC DEVICE

(71) Applicant: SONY SEMICONDUCTOR SOLUTIONS CORPORATION, KANAGAWA (JP)

(72) Inventor: KAZUHIRO TAMURA, KANAGAWA (JP)

(21) Appl. No.: 18/291,364

(22) PCT Filed: Mar. 22, 2022
(86) PCT No.: PCT/JP2022/012973

§ 371 Date: Jan. 23, 2024

(30) Foreign Application Priority Data
Aug. 17, 2021 (JP) 2021-132814

(51) Int. Cl. H01L 33/62; H01L 25/075

(52) U.S. Cl. CPC H01L 33/62; H01L 25/0756

(57) ABSTRACT

An object is to provide a semiconductor device and an electronic device that can suppress faulty connections between different chips. The semiconductor device includes: a first chip that includes an insulating layer and a plurality of wiring layers having wires formed in the insulating layer; and at least one second chip that is mounted on the first chip and includes a plurality of conductive portions, wherein the first chip includes a plurality of pad layers and connecting structures, each being formed to electrically connect the pad layer and the conductive portion, the plurality of pad layers being formed at least in the plurality of different wiring layers.

### TECHNICAL FIELD

The present disclosure relates to a semiconductor device and an electronic device.

### BACKGROUND ART

As a semiconductor device, for example, a semiconductor device having a structure described in PTL 1 is known, the structure including a semiconductor chip and another chip directly placed on a substrate constituting the semiconductor chip. Another chip may be, for example, a chip having a driving IC for driving a semiconductor element.

### Citation List

### Patent Literature

### PTL 1

JP 2003-163368A

### SUMMARY

### Technical Problem

When another chip is placed on the substrate constituting the semiconductor chip, another chip is electrically connected onto the semiconductor chip by, for example, a method for crimping another chip onto the semiconductor chip. At this point, there is a demand for suppression of faulty electrical connections between the semiconductor chip and another chip even if a pressing force applied from another chip to the semiconductor chip varies during crimping. A pressing force is likely to vary when a substrate constituting another chip has an uneven thickness. Thus, there is a demand for suppression of faulty electrical connections between the semiconductor chip and another chip even if the substrate constituting another chip has an uneven thickness.

The present disclosure has been devised in view of such circumstances. An object of the present disclosure is to provide a semiconductor device and an electronic device that can suppress faulty connections between different chips: a semiconductor chip and another chip even if another chip has an uneven thickness when being crimped onto the semiconductor chip.

### Solution to Problem

The present disclosure is, for example, (1) a semiconductor device including: a first chip that includes an insulating layer and a plurality of wiring layers having wires formed in the insulating layer; and at least one second chip that is mounted on the first chip and includes a plurality of conductive portions, wherein the first chip includes a plurality of pad layers, and connecting structures, each being formed to electrically connect the pad layer and the conductive portion, the plurality of pad layers being formed at least in the plurality of different wiring layers.

The present disclosure may be an electronic device including the semiconductor element according to (1).

### BRIEF DESCRIPTION OF DRAWINGS

FIG. 1 is a plan view illustrating a schematic configuration of an example of a semiconductor device according to a first embodiment.

FIG. 2 is a cross-sectional view schematically illustrating a state of a longitudinal section taken along line A-A in FIG. 1.

FIG. 3A is a bottom view schematically illustrating a second chip according to an example of the semiconductor device according to the first embodiment. FIG. 3B is a cross-sectional view schematically illustrating the second chip according to an example of the semiconductor device according to the first embodiment.

FIGS. 4A to 4D are cross-sectional views for explaining a method for manufacturing the semiconductor device according to the first embodiment.

FIGS. 5A and 5B are cross-sectional views for explaining the method for manufacturing the semiconductor device according to the first embodiment.

FIG. 6 is a cross-sectional view for explaining the method for manufacturing the semiconductor device according to the first embodiment.

FIG. 7 is a cross-sectional view illustrating a schematic configuration of an example of the semiconductor device according to the first embodiment.

FIGS. 8A and 8B are cross-sectional views for explaining an example of the semiconductor device according to the first embodiment.

FIG. 9 is a cross-sectional view for explaining an example of the semiconductor device according to modification example 1 of the first embodiment.

FIG. 10 is a cross-sectional view for explaining an example of the semiconductor device according to modification example 2 of the first embodiment.

FIGS. 11A and 11B are plan views for explaining an example of a semiconductor device according to a second embodiment.

FIG. 12 is a plan view for explaining an example of a semiconductor device according to a third embodiment.

FIG. 13A is a bottom view schematically illustrating a second chip according to an example of the semiconductor device according to the third embodiment. FIG. 13B is a cross-sectional view schematically illustrating the second chip according to an example of the semiconductor device according to the third embodiment.

FIG. 14 is a cross-sectional view for explaining an example of a semiconductor device according to a fourth embodiment.

FIG. 15 is an explanatory drawing illustrating an example of a grinding step of a second chip.

FIGS. 16A and 16B are explanatory drawings of an example of an electronic device in which the semiconductor device is used.

FIG. 17 is an explanatory drawing of an example of the electronic device in which the semiconductor device is used.

FIG. 18 is an explanatory drawing of an example of the electronic device in which the semiconductor device is used.

### DESCRIPTION OF EMBODIMENTS

An example according to the present disclosure will be described below with reference to the drawings. The description will be made in the following order. In the present specification and the drawings, configurations having substantially the same functional configurations are denoted by the same reference numerals, and repeated descriptions thereof are omitted.

The description will be made in the following order.
1. First Embodiment
2. Second Embodiment
3. Third Embodiment
4. Fourth Embodiment
5. Application Examples
6. Examples of Other Devices

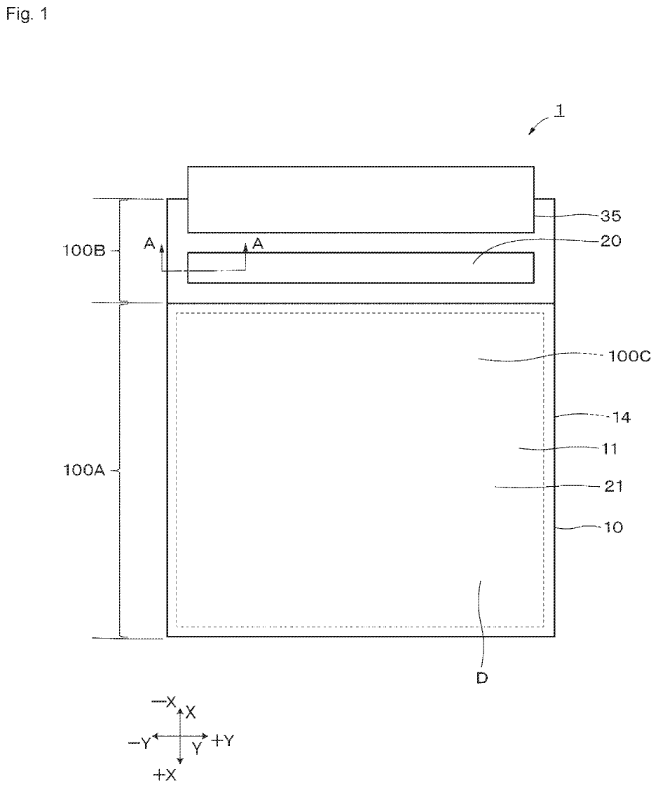

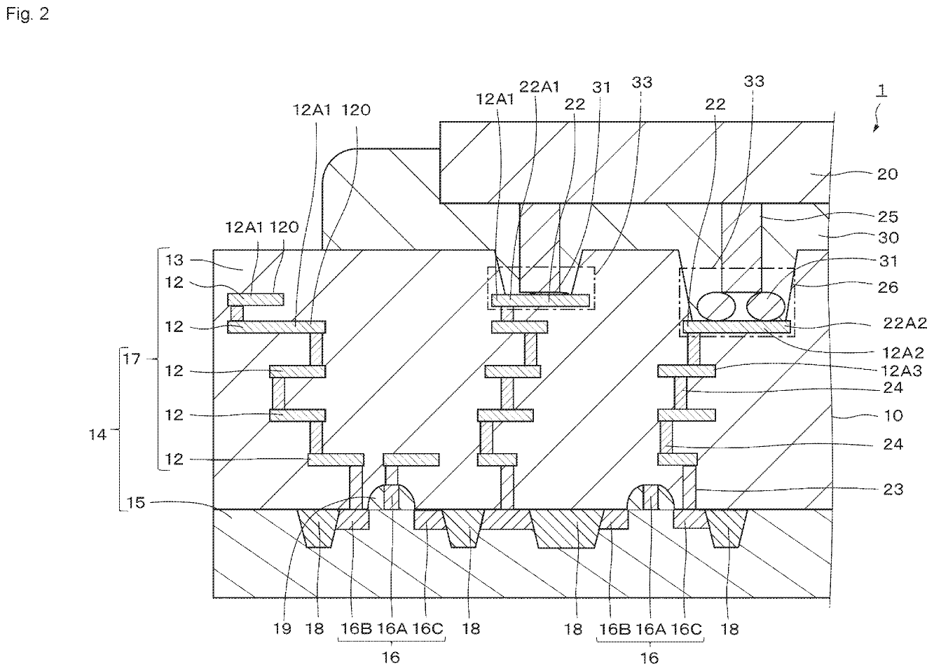

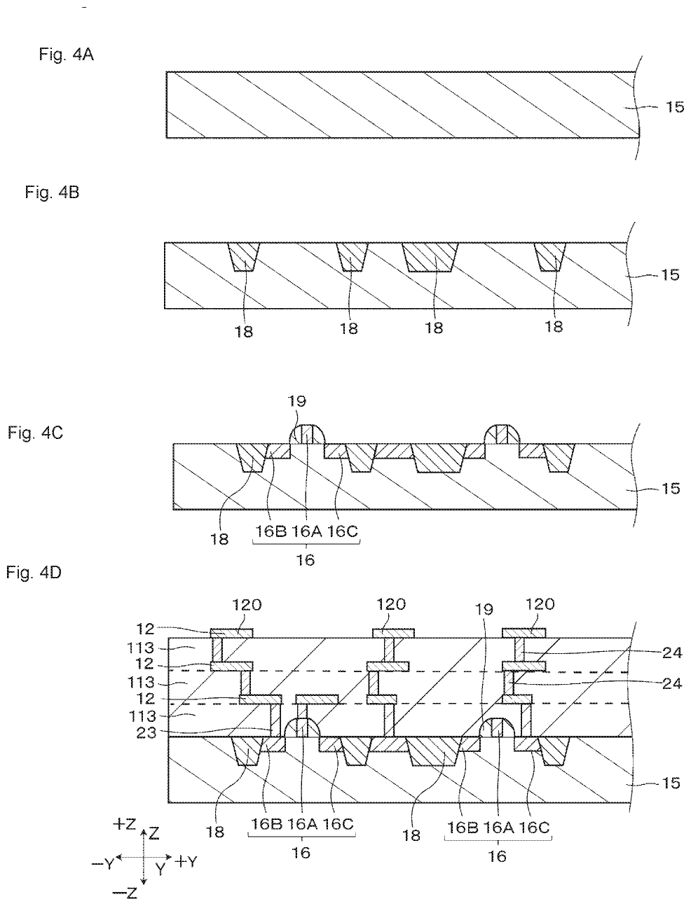

The following description is a proper specific example of the present disclosure. The contents of the present disclosure are not limited to these embodiments or the like. For convenience of explanation, longitudinal, horizontal, and vertical directions are indicated in the following description but the contents of the present disclosure are not limited to these directions. In the examples of FIGS. 1, 2, and 3, the Z-axis direction is the vertical direction (the +Z direction extends upward while the −Z direction extends downward), the X-axis direction is the longitudinal direction (the +X direction extends frontward while the −X direction extend rearward), and the Y-axis direction is the horizontal direction (the +Y direction extends rightward while the −Y direction extends leftward). The description will be made on the basis of these directions. The same applies to FIGS. 4 to 15. The relative proportions of the sizes and thicknesses of layers illustrated in the drawings including FIG. 1 are described for convenience unless otherwise specified. Actual proportions are not limited thereto. The same applies to FIGS. 2 to 15 regarding the definitions of these directions and the proportions.

A semiconductor device according to the present disclosure is not particularly limited and may be, for example, a semiconductor display device including a light emitting element. The light emitting element used for the semiconductor display device is not particularly limited and may be, for example, an OLED (Organic Light Emitting Diode) (organic EL light emitting element) or an LED (Light Emitting Diode) (semiconductor light emitting element). Moreover, as a light emitting element, a so-called micro OLED and micro LED with finer designs may be adopted from among OLEDs and LEDs.

In first to fourth embodiments below, a semiconductor device used as a display device, in particular, a semiconductor device used as a display device with an OLED serving as a light emitting element will be described as an example.

### 1 First Embodiment

### 1-1 Configuration of Semiconductor Device

As illustrated in FIGS. 1 and 2, a semiconductor device 1 according to the first embodiment includes a first chip 10 and a second chip 20. FIGS. 1 and 2 are a plan view and a cross-sectional view for explaining an example of the semiconductor device 1 according to the first embodiment.

### (Display Part Region and Outer Region)

As illustrated in FIG. 1, the semiconductor device 1 includes a display part region 100A and an outer region 100B near a display surface D. The display part region 100A is determined as a region for placing a display part, which will be described later. A display region 100C where light generated from a display part 11 is emitted outward is determined over or in the display part region 100A. In the example of FIG. 1, the display part region 100A is formed as a rectangular region on the first chip 10 in the plan view of the semiconductor device 1, the display region 100C is a region surrounded by a broken line, and the outer region 100B is a region outside of the display part region 100A on the first chip. The display part region 100A and the outer region 100B border on each other. The display surface D indicates a surface where light generated from a light emitting element in the semiconductor device 1 is drawn to the outside.

In the following description, the semiconductor device 1 has a surface (+Z direction surface) oriented to the display surface D as a first surface (top surface) and a surface (−Z direction surface) at the back side of the semiconductor device 1 as a second surface (undersurface).

### (First Chip)

The first chip 10 is a semiconductor chip. In the example of FIGS. 1 and 2, the semiconductor chip serving as the first chip 10 includes a driving substrate 14 and the display part 11 formed on the driving substrate 14. The first chip 10 includes a plurality of wiring layers 12 and an insulating layer 13 in the driving substrate 14.

### (Display Unit)

As described above, the display part 11 is formed in a part corresponding to the display part region 100A of the first chip 10. The display part 11 in the example of FIG. 1 has a structure (not illustrated) including multiple pixels and a plurality of light emitting elements placed for each of the pixels on the driving substrate 14. The light emitting elements are placed according to the pattern of the pixels. In this example, as described above, an organic EL light emitting element is used as the light emitting element. In the display part 11, an opposed substrate 21, e.g., a glass substrate may be provided over the light emitting elements. In FIG. 1, the illustration of configurations including the light emitting elements provided between the driving substrate 14 and the opposed substrate 21 is omitted for convenience of explanation. Also, in FIGS. 2 to 14, the illustration of the display part 11 is omitted for convenience of explanation.

### (Driving Substrate)

In the first chip 10, as illustrated in FIG. 2, the driving substrate 14 includes a substrate 15, semiconductor elements 16 provided on the first surface of the substrate 15, and a multilayer wiring part 17.

### (Substrate)

The substrate 15 may be made of, for example, glass or resin having low moisture and oxygen permeability, or may be made of a semiconductor that facilitates the formation of transistors and the like. Specifically, the substrate 15 may be a glass substrate, a semiconductor substrate, or a resin substrate or the like. A glass substrate contains, for example, high strain point glass, soda glass, borosilicate glass, forsterite, lead glass, or quartz glass. A semiconductor substrate contains, for example, amorphous silicon, polycrystalline silicon, or monocrystalline silicon. A resin substrate contains, for example, at least one selected from the group consisting of polymethyl methacrylate, polyvinyl alcohol, polyvinyl phenol, polyethersulfone, polyimide, polycarbonate, polyethylene terephthalate, and polyethylene naphthalate. In the example of FIG. 2, the semiconductor elements are formed on the substrate 15. In view of the ease of formation of the semiconductor elements, a silicon substrate is preferably adopted as the substrate 15.

### (Semiconductor Element)

As illustrated in the example of FIG. 2, the semiconductor elements 16 are provided on the first surface of the substrate 15. The semiconductor elements 16 may be properly selected according to, for example, the functions of the semiconductor device 1 and may be transistors of CMOS (Complementary Metal Oxide Semiconductor) or the like. The semiconductor elements 16 in FIG. 2 are transistors, each having a gate 16A, a source 16B, and a drain 16C. In this example, a side-wall oxide film 19 made of an insulating material is formed on the sides of the gate 16A. Moreover, the semiconductor elements 16 are separated from each other by an element separating layer 18. The element separating layer 18 may be made of, for example, SiO₂.

### (Multilayer Wiring Part)

The multilayer wiring part 17 is formed on the first surface of the substrate 15. The multilayer wiring part 17 includes the insulating layer 13 and the plurality of wiring layers 12. In the example of FIG. 2, the multilayer wiring part 17 is formed over the semiconductor elements 16 on the first surface of the substrate 15.

### (Wiring Layer)

The wiring layer 12 has a wire 120. In the wiring layer 12, the wire 120 is formed in a pattern corresponding to the design of the semiconductor device 1 in the plan view of the multilayer wiring part 17. The material of the wire 120 is not particularly limited and may be metallic materials such as copper, gold, silver, and aluminum. The plan view of the multilayer wiring part 17 is a view in a line of sight that is the thickness direction (Z-axis direction) of the multilayer wiring part 17.

The plurality of wiring layers 12 are spaced in the vertical direction (Z-axis direction). The number of wiring layers 12 is not particularly limited. In the example of FIG. 2, the five wiring layers 12 are stacked. The insulating layer 13 is provided between the adjacent wiring layers 12. The plurality of wiring layers 12 are provided inside of the insulating layer 13. In this case, the inside of the insulating layer 13 includes exposure of at least a part of the wiring layer 12 from an opening (e.g., a pad opening 26) provided on the insulating layer 13 as well as embedding in the insulating layer 13.

The wiring layers 12 adjacent to each other in the vertical direction are electrically connected to each other by a via 24 (Via) formed at a predetermined position. The intervals between the adjacent wiring layers 12 are determined according to various conditions including the position of a pad layer 22, which will be described later, the wiring pattern, and the wiring resistance. The via 24 may have an ordinary structure. In the structure of the via 24, a layer of a conductive material is formed on the inner wall surface of a hole portion formed at a predetermined position in the insulating layer 13 so as to connect the wiring layers 12. The properties of the conductive material forming the via 24 may be identical to those of the wire 120. In the illustration of FIG. 2, the via 24 having a solid shape is merely exemplary, and a hollow shape of the via 24 is not to be excluded.

Furthermore, in the example of FIG. 2, the wiring layer 12 at the lowest position, that is, the wiring layer 12 at the closest position to the substrate 15 is electrically connected to the semiconductor element 16 via a contact wire 23. The material of the contact wire 23 is not particularly limited. Metallic materials such as tungsten may be preferably adopted. The insulating layer 13 is also provided between the wiring layer 12 at the closest position to the substrate 15 and the substrate 15. In the part of the insulating layer 13, a contact hole is formed on the semiconductor element 16 and the contact wire 23 is placed in the contact hole.

### (Insulating Layer)

The insulating layer 13 is formed in the multilayer wiring part 17. The insulating layer 13 fills a space between the adjacent wiring layers 12. The insulating layer 13 also fills a space between the wiring layer 12 at the closest position to the substrate 15 and the substrate 15. The insulating layer 13 further covers the wiring layer 12 disposed at the farthest position from the substrate 15.

The material of the insulating layer 13 is not particularly limited. In view of high-speed signal transmission, the insulating layer 13 is preferably made of a material having a low dielectric constant (low relative permittivity material) (a so-called Low-k material).

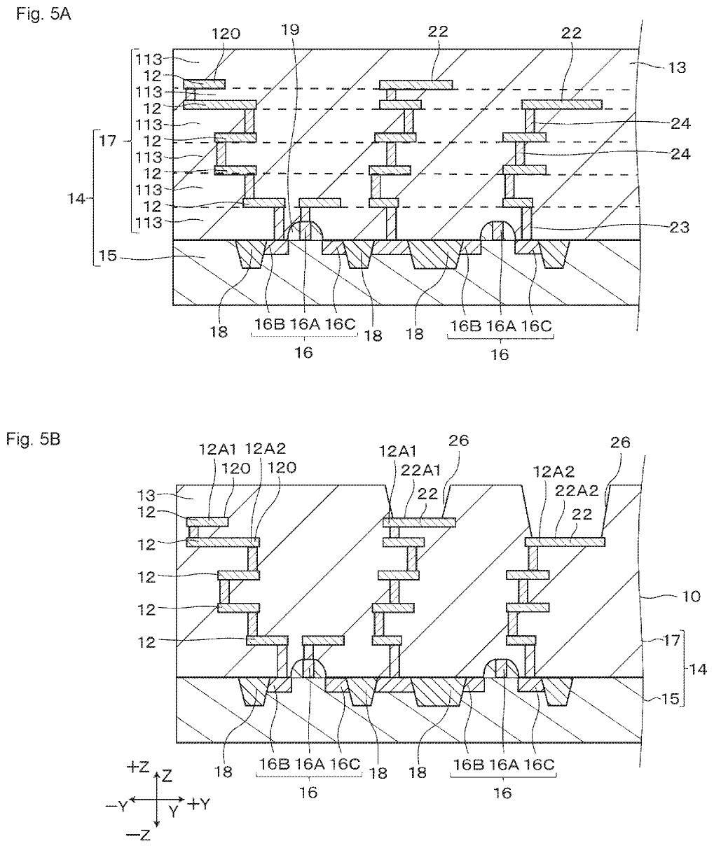

The insulating layer 13 may have a laminated structure of a plurality of layers. For example, as illustrated in FIGS. 4D, 5A, and 5B of a manufacturing method, which will be described later, the insulating layer 13 may have a laminated structure of a layer 113 filling a space between the wiring layer 12 at the closest position to the substrate 15 and the substrate 15, a layer 113 filling a space between the adjacent wiring layers 12, and a layer 113 covering the wiring layer 12 at the farthest position from the substrate 15. In the laminated structure, the adjacent layers are integrated in a part where the wiring layers are not formed. In other words, in this case, the insulating layer 13 has a laminated structure of the plurality of layers 113. If the insulating layer 13 has a laminated structure of the plurality of layers 113, the number of stacked layers is not particularly limited. Whether the layers 113 forming the insulating layer 13 are to be made of the same material or different materials is not particularly limited. In the examples of FIGS. 4D, 5A, and 5B, the layers 113 are all made of the same material and the adjacent layers 113 are integrated in contact with each other in a part where the wiring layers 12 are not formed. In FIGS. 4D and 5A, the border between the adjacent layers 113 is indicated by a broken line.

### (Pad Layer)

The first chip 10 includes pad layers 22. The pad layer 22 can be used as a connecting terminal for electrically connecting a chip different from the first chip 10 to the first chip 10. The plurality of pad layers 22 are provided in the first chip 10. In the semiconductor device 1 according to the first embodiment, at least two different ones of the wiring layers 12 of the first chip 10 include the pad layer 22. In the example of FIG. 2, a first wiring layer 12A1 and a second wiring layer 12A2 each include the pad layer 22. In this configuration, the n-th wiring layer 12 from the top is denoted as an n-th wiring layer 12An (n is an integer equal to or larger than 2). Thus, the wiring layers 12 are arranged with the insulating layer 13 interposed therebetween such that the first wiring layer 12A1, the second wiring layer 12A2, and a third wiring layer 12A3 are sequentially placed, starting from the uppermost wiring layer 12. In the present specifications, the first wiring layer 12A1, the second wiring layer 12A2, . . . , and the n-th wiring layer 12An are simply referred to as the wiring layers 12 unless otherwise specified.

In the example of FIG. 2, the wiring layers 12 not including the pad layers 22 are absent between the plurality of wiring layers 12 including the pad layers 22 (the first wiring layer 12A1 and the second wiring layer 12A2). However, FIG. 2 is merely exemplary. The semiconductor device 1 may include one or two or more wiring layers 12 not including the pad layers 22. This point will be described in modification example 2. The pad layer 22 in the first wiring layer 12A1 may be referred to as a first pad layer 22A1, and the pad layer 22 in the second wiring layer 12A2 may be referred to as a second pad layer 22A2. The first pad layer 22A1 and the second pad layer 22A2 or the like are simply referred to as the pad layers 22 unless otherwise specified.

The first pad layer 22A1 and the second pad layer 22A2 as the pad layers 22 are each used as a connecting terminal electrically connected to the conductive portion (a bump 25 in the example of FIG. 2) of the second chip 20, which will be described later. Moreover, an opening (pad opening 26) is formed above the predetermined region of the pad layer 22. A space above the predetermined region on the first surface of the first pad layer 22A1 is opened, and the pad opening 26 is formed as the opened portion. Like the first pad layer 22A1, the second pad layer 22A2 has a space opened above the predetermined region on the first surface, and the pad opening 26 is formed as the opened portion.

The number of formed pad layers 22 and the positions of the pad layers 22 (the positions in a plan view of the semiconductor device 1) are not particularly limited, but the pad layers 22 are provided under the conditions of the number and positions of the pad layers 22 according to the number and positions of conductive portions provided in the second chip 20, which will be described later. The material of the pad layer 22 is not particularly limited if the material is conductive. The same material as the wire 120 may be used. A metallic material can be properly used as in the wire 120.

### (Difference in Position of Pad Layer)

In the semiconductor device 1, the pad layers 22 provided in the different wiring layers 12 are located at different positions. At this point, as illustrated in FIG. 7, a positional difference M between the uppermost pad layer 22 and the lowermost pad layer 22 in the vertical direction (Z-axis direction) is preferably equal to or smaller than a half of the mean particle diameter of conductive particles 31, which will be described later. As will be described later, in many cases, the mean particle diameter of the conductive particles 31 falls within a range of about 3 μm to about 10 μm. FIG. 7 is a schematic cross-sectional view for explaining the semiconductor device 1 according to the first embodiment. In the example of FIG. 7, among the wiring layers 12 including the pad layers 22, the first pad layer 22A1 closest to the first surface and the second pad layer 22A2 closest to the second surface are located at different positions. The positional difference M between the first pad layer 22A1 and the second pad layer 22A2 is preferably equal to or smaller than a half of the mean particle diameter of the conductive particles 31. In this case, when the second chip 20, an anisotropic conductive film 30, which will be described later, and the first chip 10 are crimped, the conductive particles 31 held between the bump 25 and the first pad layer 22A1 and the conductive particles 31 held between the bump 25 and the second pad layer 22A2 can be properly deformed by a pressure applied between the bump 25 and the pad layer 22. In the example of FIG. 2, the conductive particles 31 held between the first pad layer 22A1 and the bump 25 and the conductive particles 31 held between the second pad layer 22A2 and the bump 25 can be squeezed (deformed) to substantially a half of the size before crimping.

The positions of the pad layers 22 indicate positions in the thickness direction (Z-axis direction) of the multilayer wiring part 17. The positional difference M between the plurality of pad layers 22 indicates a distance between the plurality of pad layers 22 along the vertical direction (Z-axis direction).

### (Second Chip)

In the semiconductor device 1, at least one second chip 20 is mounted on (the first surface of) the first chip 10. In the example of FIG. 1, the single second chip 20 is mounted on the semiconductor chip provided as the first chip 10. Moreover, the second chip 20 is disposed in the outer region 100B. Thus, the size of the second chip 20 is smaller than the size of the first chip 10.

The second chip 20 is an IC chip in which electronic components and an integrated circuit corresponding to the functions or the like are mounted on a substrate (not illustrated), and the IC chip is different from the first chip 10. Examples of the IC chip may include display driver ICs (Display Driver Integrated Circuits; DDIC) and ICs (Integrated Circuits) for a memory, a sensor, and image processing.

### (Thickness of Second Chip)

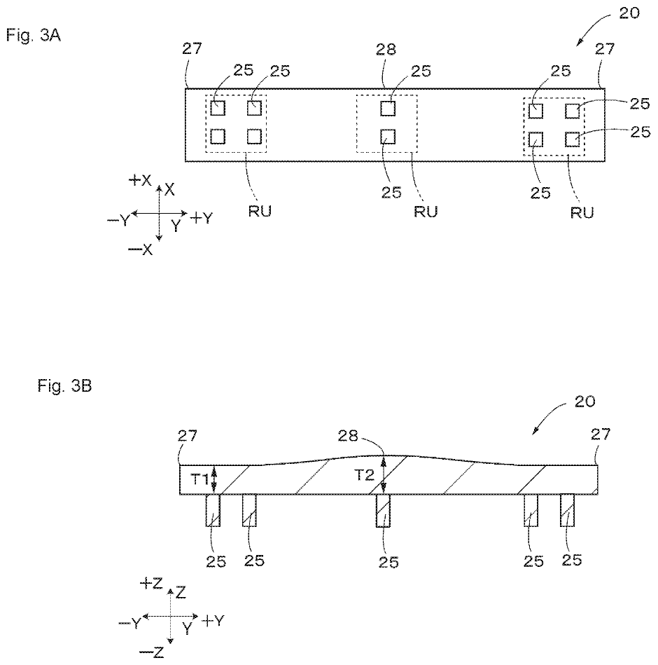

The second chip 20 may have a uniform or uneven thickness. In the example of FIG. 3B, the thickness of the second chip 20 is uneven (nonuniform). In this case, the distribution of the thickness of the second chip 20 is not particularly limited. The thickness distribution of the second chip 20 may be determined according to the distribution of the dense state of the bumps 25, which will be described later. In the example of FIG. 3B, a thickness T1 of the second chip 20 in the vicinity of two ends 27 separated in the longitudinal direction (the lateral direction (Y-axis direction) in FIG. 3B) of the second chip 20 is smaller than a thickness T2 of the second chip 20 at a central portion 28 of the second chip 20. It is assumed that the thickness of the second chip 20 indicates the thickness of the second chip 20 except for the bump 25. It is assumed that the vicinity of the ends 27 indicates a portion from one end face of the second chip 20 to a predetermined position near the central portion 28. It is assumed that the central portion 28 indicates a portion from the center of the second chip 20 to a predetermined position near the end 27. FIG. 3B is a cross-sectional view illustrating an example of the second chip 20 and corresponds to the cross-sectional view of the second chip 20 in FIG. 3A. FIG. 3A is a bottom view illustrating the example of the second chip 20.

The distribution state of the thickness of the second chip 20 in the example of FIG. 3B tends to be implemented in the manufacturing process of the semiconductor device 1 when the step of grinding the first surface (the surface on which the bumps 25 are not mounted) of the second chip 20 is performed after the bumps 25 are provided on the second chip 20.

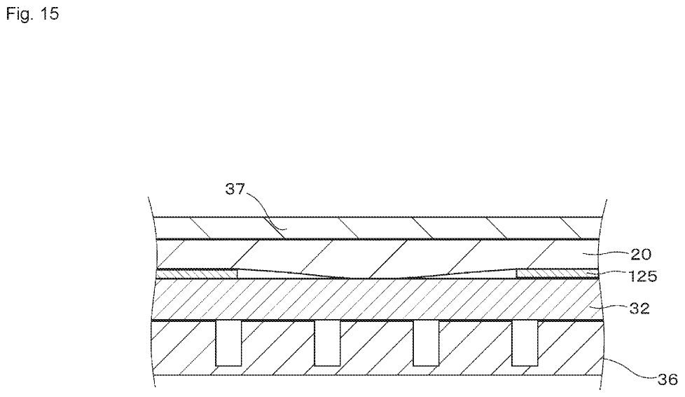

In the polishing step, as illustrated in FIG. 15, a back grind tape (BG tape 32) is provided as a protective tape on the second surface of the second chip 20 so as to cover a bump group 125 including the plurality of bumps 25, and then the first surface of the second chip 20 is ground by a grinding part 37 of a grinder while the placement surface of the BG tape 32 is fixed on a suction part 36 of a suction machine. FIG. 15 is an explanatory drawing illustrating an example of the grinding step of the second chip 20. During the grinding step, the second chip 20 is more likely to be ground in a portion containing the bumps 25 at a high density than in a portion containing the bumps 25 at a low density. Thus, in the second chip 20, the thickness distribution of the second chip 20 tends to be formed according to the distribution of the dense state of the bumps 25. The suction machine and the grinder may be, for example, machines ordinarily used in the grinding step of the semiconductor chip. The bump group 125 indicates a group of the bumps 25 disposed in a portion determined as a relatively dense portion of the bumps 25.

### (Conductive Portion)

The second surface of the second chip 20 faces the first surface of the first chip 10. The surface facing the first chip 10 has a plurality of conductive portions.

The conductive portions are electrically connected to the integrated circuit mounted on the second chip 20. In the semiconductor device 1, a connecting structure 33 that electrically connects the conductive portions and the pad layers 22 of the first chip 10 is formed.

The conductive portions may be formed like layers on the back side (second surface) of the second chip 20 or may be formed like protrusions. In the example of FIG. 2, the conductive portions are conductive protrusions (bumps 25 (Bump)) extending from the back side (second surface) of the second chip 20. In the description of the first embodiment, the bumps 25 provided as the conductive portions are used as an example. Also, in second to fourth embodiments, which will be described later, the bumps 25 provided as the conductive portions will be described as an example.

### (Bumps)

The bumps 25 provided as the conductive portions are configured to be electrically connected to the desired pad layers 22 of the first chip 10. The kind of bumps 25 is not particularly limited. The bumps 25 may be, for example, pillar bumps or stud bumps. The material of the bumps 25 may be, for example, gold, silver, copper, tin, or an alloy thereof. In the example of FIG. 3A, which will be described later, the bumps 25 are rectangular in cross section. The shape is not limited thereto. For example, the bumps 25 may be circular in cross section. The bump 25 preferably has a smaller size than the pad layer 22 in cross section in view of ease of connection of the bump 25 to the pad layer 22. The number of formed bumps 25 is determined according to, for example, the contents of the integrated circuit and electronic components that are mounted on the second chip 20. In the example of FIGS. 2 and 3, the plurality of bumps 25 are provided. The sizes of the bumps 25 are not particularly limited. In the example of FIG. 2, the bumps 25 have substantially the same size.

### (Density of Bumps)

The density distribution of the bumps 25 (the distribution of the dense state of the bumps 25) in the second chip 20 may be determined according to the circuit design of the second chip 20. In the example of FIGS. 3A and 3B, the second chip 20 is shaped like a long slender rectangle in a plan view of the second chip 20, and the bumps 25 near the two ends 27 separated in the longitudinal direction of the second chip 20 have a higher density than the bumps 25 at the central portion 28 of the second chip 20. It is assumed that the density of the bumps 25 indicates the number of formed bumps 25 per unit area. In the example of FIG. 3A, a region that determines the unit area (unit region RU) is represented as a region surrounded by a broken line. In this example, the number of bumps 25 formed in the unit region RU determined near the ends 27 is equal to or larger than the number of bumps 25 formed in the unit region RU determined at the central portion 28.

As described above, in the example of FIG. 3B, the thickness T1 of the second chip 20 near the ends 27 of the second chip 20 is smaller than the thickness T2 of the second chip 20 at the central portion 28 of the second chip 20. Thus, the plurality of bumps 25 are formed on the second chip 20 such that the density of the bumps 25 formed in a portion (central portion 28) where the second chip 20 has a relatively large thickness is lower than the density of the bumps 25 formed in portions (ends 27) where the second chip has a relatively small thickness.

### (Connecting Structure)

In the semiconductor device 1, as described above, the connecting structure 33 that electrically connects the pad layers 22 and the conductive portions is formed. The second chip 20 and the first chip 10 are electrically connected to each other via the connecting structure 33. If the conductive portions are the bumps 25, as illustrated in FIG. 2, the connecting structure 33 is a structure that electrically connects the pad layer 22 and the bump 25. The pad layer 22 and the bump 25 may be directly connected to each other or may be electrically connected to each other via the conductive particles 31, which will be described later. Alternatively, the connecting structure 33 may be a structure including a portion where the pad layer 22 and the bump 25 are directly connected to each other and a portion where the pad layer 22 and the bump 25 are electrically connected to each other via the conductive particles 31. In FIG. 2, the connecting structure 33 is illustrated as a portion surrounded by a chain line.

In the example of FIG. 2, the structure in which the pad layers 22 and the bumps 25 are electrically connected to each other via the conductive particles 31 is implemented by providing a resin film containing the conductive particles 31 between the first chip 10 and the second chip 20.

### (Anisotropic Conductive Film)

As the resin film containing the conductive particles 31, the anisotropic conductive film (Anisotropic Conductive Film; ACF) 30 is preferably used as shown in the example of FIG. 2. In the anisotropic conductive film 30, the conductive particles 31 are contained while being dispersed over the interior of the anisotropic conductive film 30. By using the anisotropic conductive film 30, the connecting structure 33 can be formed as follows: the anisotropic conductive film 30 is disposed on the first surface of the first chip 10, and the second chip 20 is disposed on the anisotropic conductive film 30. At this point, the second chip 20 and the first chip 10 are positioned such that the tips of the bumps 25 of the second chip 20 are directed toward the pad layers 22 of the first chip 10. Thereafter, the second chip 20, the anisotropic conductive film 30, and the first chip 10 are crimped (hereinafter referred to as a crimping step). During the crimping step, the anisotropic conductive film 30 is partially placed into the pad opening 26 above the pad layer 22. The conductive particles 31 contained in the anisotropic conductive film 30 are then held between the bump 25 and the pad layer 22, so that the bump 25 and the pad layer 22 are electrically connected to each other via the conductive particles 31. In view of effective conductivity of the conductive particles 31, the conductive particles 31 held between the bump 25 and the pad layer 22 are preferably squeezed (deformed) during the crimping step.

In the semiconductor device 1, the degrees of deformation (deformation degree) of the conductive particles 31 may vary with a distance between the bump 25 and the pad layer 22. In the example of FIG. 2, a distance between the bump 25 and the second pad layer 22A2 is larger than a distance between the bump 25 and the first pad layer 22A1. In this case, the deformation degree of the conductive particles 31 located between the bump 25 and the first pad layer 22A1 is larger than the deformation degree of the conductive particles 31 located between the bump 25 and the second pad layer 22A2. In the example of FIG. 2, the conductive particles 31 located between the bump 25 and the first pad layer 22A1 are deformed close to a completely squeezed state. The conductive particles 31 located between the bump 25 and the second pad layer 22A2 are also preferably squeezed to enhance the effect of conductivity by the conductive particles 31. From this perspective, the conductive particles 31 held between the bump 25 and the pad layer 22 are preferably squeezed between the bump 25 and the pad layer 22 to a mean particle diameter that is equal to or smaller than a half of the mean particle diameter of the conductive particles 31 before the conductive particles 31 are held between the bump 25 and the pad layer 22.

### (Deformation Degree of Conductive Particles)

As shown in FIG. 7, for the conductive particles 31 held between the bump 25 and the pad layer 22, the deformation degree of the conductive particles 31 indicates a rate of change ((W1−W2)/W1) of a mean particle diameter (W2) of the conductive particles 31 along the crimping direction (−Z direction in the example of FIG. 7) after the crimping step with respect to a mean particle diameter (W1) of the conductive particles 31 along the crimping direction before the crimping step.

### (Mean Particle Diameter of Conductive Particles)

The mean particle diameter of the conductive particles 31 is preferably a value smaller than the opening diameter of the pad opening 26. Thus, when the anisotropic conductive film 30 is partially placed into the pad opening 26 above the pad layer 22, the conductive particles 31 are also easily placed into the pad opening 26. Specifically, in many cases, the mean particle diameter of the conductive particles 31 falls within the range of about 3 μm to about 10 μm as described above. As the mean particle diameter (W1) of the conductive particles 31 along the crimping direction before the crimping step, an arithmetic mean value of the sizes (particle diameters) of ten of the conductive particles 31 along the crimping size is preferably adopted, the ten conductive particles 31 being arbitrarily selected in a portion that is assumed to be a portion held between the bump 25 and the pad layer 22 in the anisotropic conductive film 30. However, as the mean particle diameter (W1) of the conductive particles 31, an arithmetic mean value of the sizes (particle diameters) of ten of the conductive particles 31 along the crimping size may be adopted after the ten conductive particles 31 are arbitrarily selected in the overall anisotropic conductive film 30. After the crimping step, the mean particle diameter (W2) of the conductive particles 31 along the crimping direction indicates an arithmetic mean value of the sizes (particle diameters) of tens of the conductive particles 31 along the crimping direction, the ten conductive particles 31 being arbitrarily selected from the conductive particles 31 held between the bump 25 and the pad layer 22 (when the number of conductive particles 31 is smaller than ten, all the conductive particles 31 held between the bump 25 and the pad layer 22).

### (Positional Relationship Between Bump and Pad Layer)

The bump 25 and the pad layer 22 are formed at positions so as to face each other. If the second chip 20 has an uneven thickness as illustrated in the example of FIG. 3B, the bump 25 formed in a portion where the second chip 20 has a relatively large thickness and the bump 25 formed in a portion where the second chip 20 has a relatively small thickness are preferably connected to the pad layers 22 formed in the different wiring layers 12 as illustrated in FIGS. 8A and 8B. FIGS. 8A and 8B are explanatory drawings of an example in which the second chip 20 has an uneven thickness. FIG. 8A illustrates a state of the first chip 10 and the second chip 20 during the crimping step. FIG. 8B illustrates an example of the semiconductor device 1 after the crimping step. In FIG. 8A, an arrow P indicates a crimping direction when the second chip 20 is crimped onto the first chip 10.

In the example of FIGS. 8A and 8B, as for the pad layer 22 connected to the bump 25 formed in a portion where the second chip 20 has a relatively small thickness, the position is located higher than (near the first surface) the pad layer 22 connected to the bump 25 formed in a portion where the second chip 20 has a relatively large thickness. In other words, in these examples, at a position where the second chip 20 has a relatively small thickness, the formed bump 25 is connected to the first pad layer 22A1 located on the upper side of the first chip 10 among the pad layers 22, whereas at a position where the second chip 20 has a relatively large thickness, the formed bump 25 is connected to the second pad layer 22A2 located lower than the first pad layer 22A1.

### (External Connecting Terminal)

As illustrated in the example of FIG. 1, the first chip 10 may be provided with an external connecting terminal 35 for connection to a device other than the semiconductor device 1. However, this does not prohibit the exclusion of the external connecting terminal 35 in the semiconductor device 1.

### 1-2 Manufacturing Method

Referring to FIGS. 4 to 6, a method for manufacturing the semiconductor device 1 will be described below. The semiconductor device 1 in FIG. 2 will be described as an example. The description and explanation of the formation of the display part 11 are omitted for convenience of explanation. In FIGS. 4 to 6, the description of the display part 11 is omitted. The description of the display part 11 is omitted also in FIGS. 7 to 15.

The substrate 15 is prepared (FIG. 4A), the element separating layer 18 is embedded into the first surface of the substrate 15, and then the semiconductor element 16 is formed (FIGS. 4B and 4C). For example, an ordinary method for forming a semiconductor element may be used as appropriate for the step of forming the element separating layer 18 and the step of forming the semiconductor element 16.

As illustrated in FIG. 4D, on the first surface of the substrate 15, the layers 113 forming the insulating layer 13 are provided over the semiconductor element 16. The layers 113 are made of a material forming the insulating layer 13. Thereafter, the step of forming the contact wires 23 and the step of forming the wiring layers 12 are performed. Furthermore, the step of forming the layers 113 covering the wiring layers 12, the step of forming the vias 24, and the step of forming the wiring layers 12 are performed. By sequentially performing the step of forming the layers 113, the step of forming the vias 24, and the step of forming the wiring layers 12, the wiring layers 12 are formed to be stacked with the layers 113 interposed therebetween as illustrated in FIG. 4D. FIG. 4D illustrates a state in which the three layers 113 and the three wiring layers 12 are formed from the closest position to the substrate 15.

Moreover, the step of forming the layers 113, the step of forming the vias 24, and the step of forming the wiring layers 12 are repeatedly performed. By performing the steps of forming the layers 113 and the wiring layers 12 and the step of forming the vias 24 thus, the wiring layers 12 are formed to the farthest position from the substrate 15 (the uppermost position (a position on the first surface)). The example of FIG. 5A illustrates a state in which the six layers 113 and the five wiring layers 12 are formed. At this point, the insulating layer 13 is formed by the plurality of layers 113, and the multilayer wiring part 17 is formed by the insulating layer 13 and the plurality of wiring layers 12. After the multilayer wiring part 17 is formed, as illustrated in FIG. 5B, the pad openings 26 are formed above the positions of the pad layers 22. The first chip 10 is formed thus. In the step of forming the contact wires 23, the step of forming the layers 113, the step of forming the wiring layers 12, the step of forming the vias 24, and the step of forming the pad openings 26, for example, methods used for a method for manufacturing an ordinary semiconductor chip may be used as appropriate.

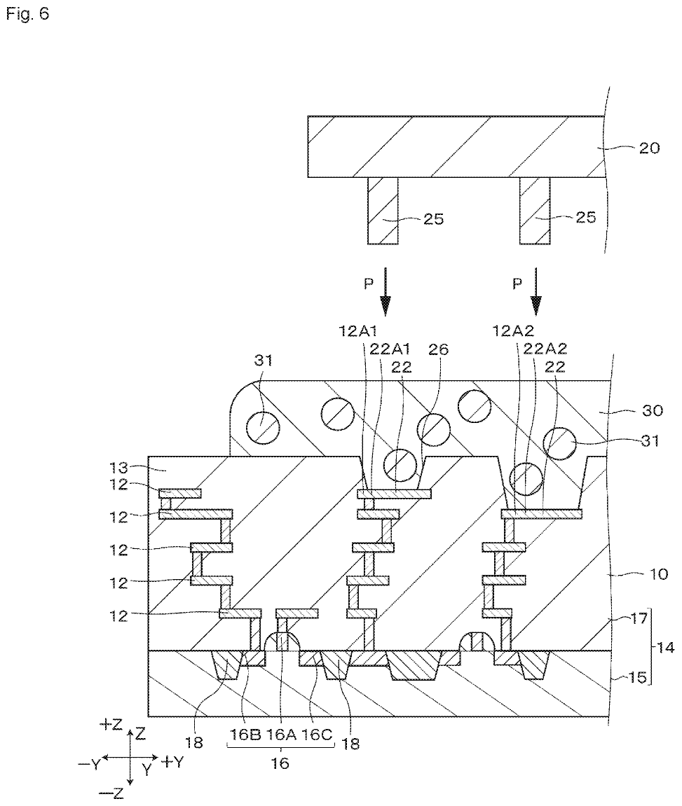

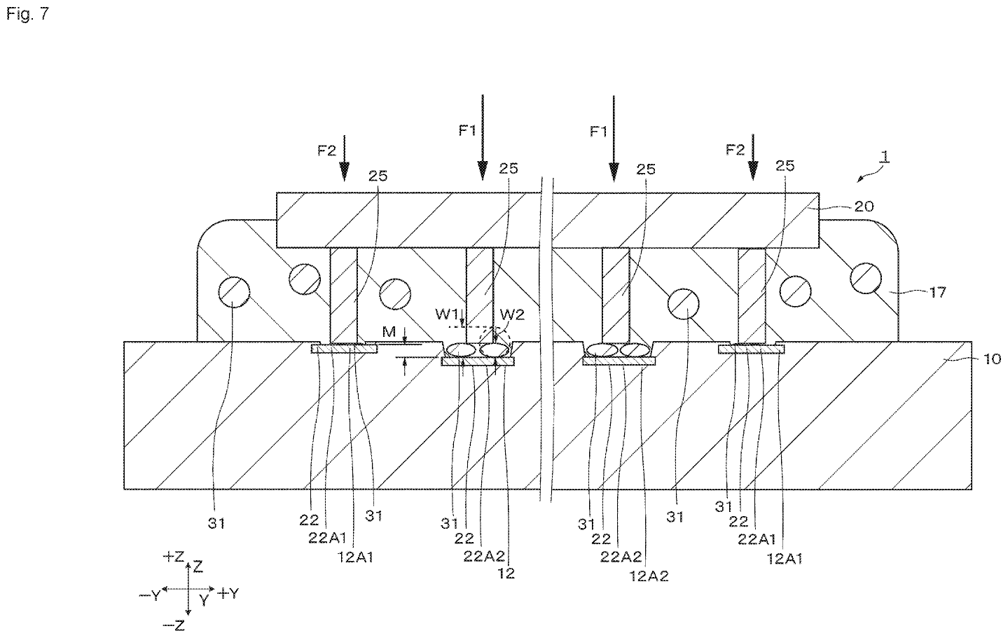

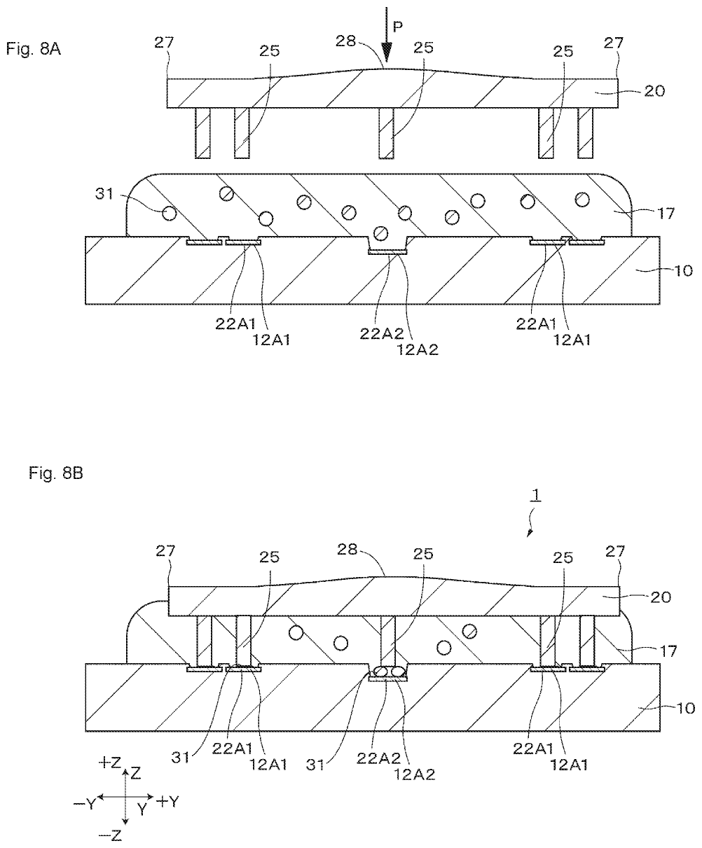

On the first chip 10, as illustrated in FIG. 6, the anisotropic conductive film 30 is provided over the first surface of the first chip 10 (a surface where the pad openings 26 are formed in FIG. 6). Furthermore, the second chip 20 is disposed on the first surface of the anisotropic conductive film 30. At this point, the second chip 20 is positioned such that the bumps 25 of the second chip 20 and the pad layers 22 of the first chip 10 are opposed to each other with the anisotropic conductive film 30 interposed therebetween. Thereafter, the crimping step is performed. The crimping step can be performed by applying, for example, a pressure from the second chip 20 to the first chip 10 in the direction of an arrow P (crimping direction). By the crimping step, the second chip 20 and the first chip 10 are crimped with the anisotropic conductive film 30 interposed therebetween. The semiconductor device 1 is obtained thus.

### 1-3 Operation and Effect

If a connecting structure, in which a conductive portion is electrically connected to a pad layer of a first chip by crimping a second chip onto the first chip, is formed in a conventional semiconductor device, suppression of faulty electrical connections between the pad layer and the conductive portion is demanded.

In a semiconductor device, in particular, the step of grinding a second chip may be performed in the step of fabricating the second chip. When the grinding step is performed, the second chip may have an uneven thickness. If the second chip has an uneven thickness, a pressure applied to a first chip from the second chip may vary during the crimping step. In this case, the semiconductor device may be obtained such that the strength of connection to the first chip varies among positions in the second chip.

Hence, there is a demand for a technique for suppressing faulty connections in a connecting structure that electrically connects a conductive portion of a second chip and a pad layer of a first chip even if a pressure from the second chip to the first chip varies due to various factors including an uneven thickness of the second chip.

In the semiconductor device 1 of the first embodiment, as illustrated in FIG. 7, the connecting structure 33 that electrically connects the conductive portion (bump 25) of the second chip 20 and the pad layer 22 of the first chip 10 is formed. The pad layers 22 are formed in the different wiring layers 12. Thus, the pad layers 22 are located at multiple positions in the first embodiment. According to the first embodiment configured thus, for example, if a pressure F1 and a pressure F2 are applied to different portions of the first chip 10 from the second chip 20 as illustrated in FIG. 7, the position of the pad layer 22 in the portion that receives the pressure F1 larger than the pressure F2 on the first chip 10 can be set lower than (near the −Z side) the pad layer 22 in the portion that receives the pressure F2. This can suppress faulty connections in the connecting structure that electrically connects the conductive portion of the second chip 20 and the pad layer 22 of the first chip 10 even if the pressure F1 is applied to some portions of the first chip 10 and the pressure F2 is applied to other portions of the first chip 10 from the second chip 20. Thus, the semiconductor device 1 according to the first embodiment can suppress the occurrence of faulty connections between different chips, that is, the first chip 10 and the second chip 20.

In the semiconductor device 1 according to the first embodiment, in particular, if the second chip 20 has an uneven thickness as illustrated in FIGS. 8A and 8B, the positions of the pad layers 22 of the first chip 10 can be adjusted according to the thickness of the second chip 20. Specifically, as illustrated in FIG. 8B, the pad layer 22 connected to the bump 25 formed in a portion where the second chip 20 has a relatively small thickness can be located higher than the pad layer 22 connected to the bump 25 formed in a portion where the second chip 20 has a relatively large thickness. Hence, even if a pressure applied from the second chip to the first chip varies due to an uneven thickness of the second chip 20, the strength of connection to the first chip 10 can be substantially equalized regardless of positions in the second chip 20. As described above, even if the second chip 20 has an uneven thickness, the semiconductor device 1 according to the first embodiment can suppress faulty connections in the connecting structure 33 that electrically connects the bump 25 of the second chip 20 and the pad layer 22 of the first chip 10.

A modification example of the semiconductor device 1 according to the first embodiment will be described below.

### 1-4 Modification Example

### Modification Example 1

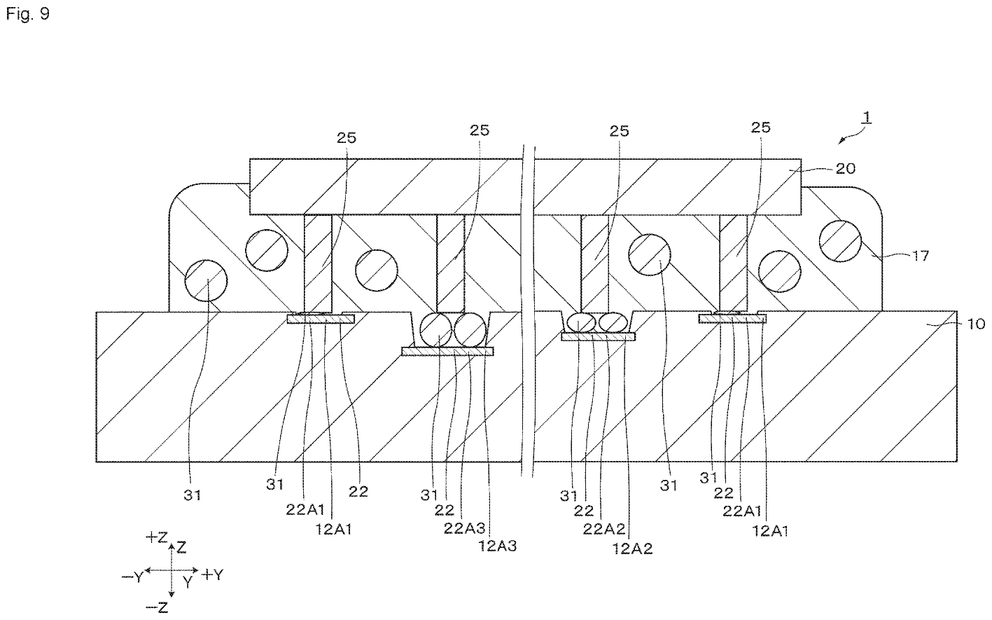

Referring to the example of FIG. 2, the first embodiment was described such that the pad layers 22 are provided in the two different wiring layers 12 among the wiring layers 12 of the first chip 10. The first embodiment is not limited to this example. As illustrated in FIG. 9, the three or more different wiring layers 12 may include the pad layers 22 (referred to as modification example 1). FIG. 9 is an explanatory drawing of an example of the semiconductor device 1 according to modification example 1 of the first embodiment.

In the example of the semiconductor device 1 in FIG. 9, the first wiring layer 12A1, the second wiring layer 12A2, and the third wiring layer 12A3 sequentially include the pad layers 22 (the first pad layer 22A1, the second pad layer 22A2, and a third pad layer 22A3) from the first surface to the second surface. The pad layers 22 provided in the three wiring layers 12 are electrically connected to the bumps 25 of the second chip 20.

Even if variations in pressure applied to the first chip 10 from the second chip 20 increase, the semiconductor device 1 according to modification example 1 can suppress faulty connections in the connecting structure 33 that electrically connects the bump 25 of the second chip 20 and the pad layer 22 of the first chip 10.

### Modification Example 2

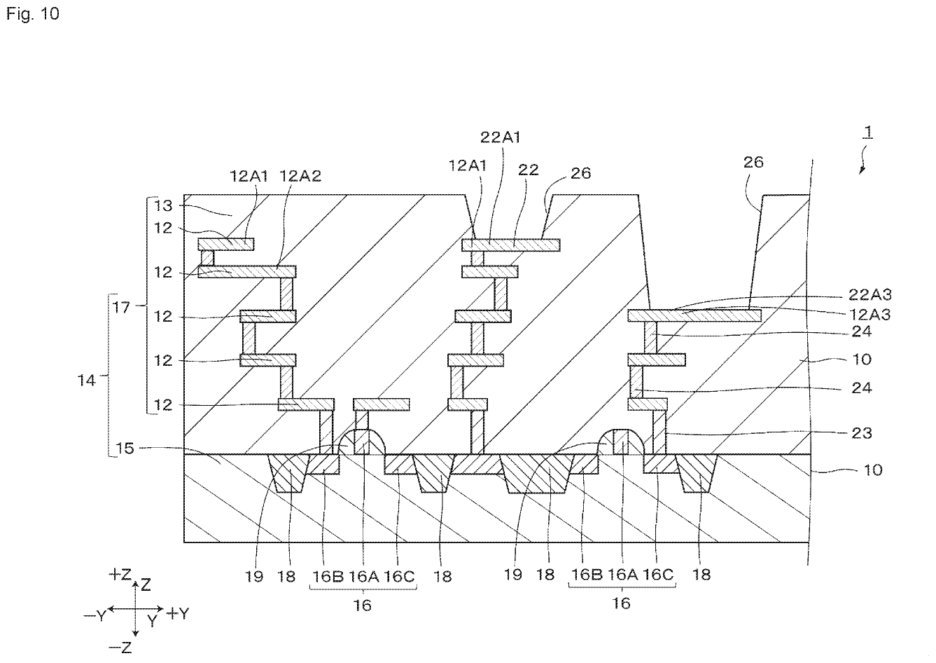

In the semiconductor device 1 according to the first embodiment, the wiring layer 12 not including the pad layer 22 is absent between the different wiring layers 12 including the pad layers 22 among the wiring layers 12 of the first chip 10. The first embodiment is not limited to this configuration. In the first embodiment, as illustrated in FIG. 10, the wiring layer 12 not including the pad layer 22 may be provided between the different wiring layers 12 including the pad layers 22 (referred to as modification example 2). FIG. 10 is an explanatory drawing of an example of the semiconductor device 1 according to modification example 2 of the first embodiment. In FIG. 10, the illustration of the anisotropic conductive film 30 and the second chip 20 is omitted for convenience of explanation.

In the semiconductor device 1 in the example of FIG. 10, the first wiring layer 12A1 and the third wiring layer 12A3 sequentially include the pad layers 22 from the first surface to the second surface. The pad layers 22 provided in the wiring layers 12 are electrically connected to the bumps 25 of the second chip 20. The formation of the pad layer 22 is avoided in the second wiring layer 12A2 provided between the first wiring layer 12A1 and the third wiring layer 12A3. The example of FIG. 10 is merely exemplary. The two or more wiring layers 12 not including the pad layers 22 may be formed between the different wiring layers 12 including the pad layers 22.

The semiconductor device 1 according to modification example 2 can obtain the same effect as modification example 1.

A semiconductor device according to a second embodiment will be described below.

### 2 Second Embodiment

### [2-1 Configuration of Semiconductor Device]

A semiconductor device 1 according to a second embodiment includes a plurality of second chips 20 mounted on a first chip 10. Other configurations of the semiconductor device 1 according to the second embodiment may be formed like the semiconductor device 1 according to the first embodiment. Thus, a description of other configurations is omitted.

### (Second Chip)

In the semiconductor device 1 according to the second embodiment, the mounting positions of the plurality of second chips 20 on the first chip 10 are not particularly limited but the second chips 20 are preferably disposed in the outer region 100B described in the first embodiment.

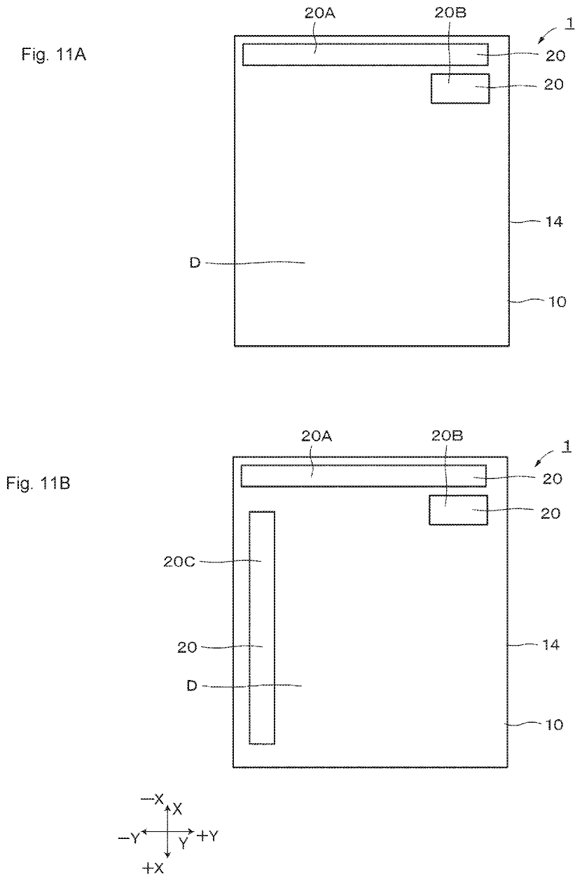

The number of second chips 20 is not particularly limited. For example, as illustrated in FIG. 11A, two second chips 20A and 20B may be mounted on the first chip 10. Furthermore, as illustrated in FIG. 11B, three second chips 20A, 20B, and 20C may be mounted on the first chip 10. In the examples of FIGS. 11A and 11B, the second chips 20 are provided on a display surface D. FIG. 11A and FIG. 11B are plan views for describing an example of the semiconductor device 1 according to the second embodiment. In FIGS. 11A and 11B, the illustration of an external connecting terminal 35 and a display part 11 is omitted for convenience of explanation. In the present specification, the second chips 20A, 20B, and 20C are referred to as the second chips 20 unless otherwise specified.

The shapes of the plurality of second chips 20 are not particularly limited. The plurality of second chips 20 may have the same shape or different shapes. The plurality of second chips 20 may have the same function or different functions. Bumps 25 provided on the plurality of second chips 20 may have the same shape or different shapes. In the example of FIG. 11A, the bumps 25 provided on the second chip 20A and the bumps 25 provided on the second chip 20B may have the same shape or different functions. The same applies to the size and material of the bumps 25. If the plurality of second chips 20 are irregular in thickness, irregularities in thickness may vary among the plurality of second chips 20.

### (Connecting Structure)

In the semiconductor device 1 according to the second embodiment, a connecting structure 33 is formed for each of the second chips. For example, in the example of FIG. 11A, the bumps 25 of the second chip 20A are connected to pad layers 22 formed in a portion of the first chip 10, the portion corresponding to the second chip 20A. The bumps 25 of the second chip 20B are connected to pad layers 22 formed in a portion of the first chip 10, the portion corresponding to the second chip 20B. In other words, in the semiconductor device 1, the connecting structure 33 is formed between the second chip 20A and the first chip 10 and the connecting structure 33 is formed between the second chip 20B and the first chip 10.

The pad layers 22 of the first chip 10 are determined depending on the second chips 20 including the bumps 25 to be connected to the pad layers 22. Thus, in a comparison between the connecting structures 33 corresponding to the different second chips 20, the pad layers 22 forming the connecting structures 33 may vary in size. For example, in the example of FIG. 11A, in a comparison between the size of the pad layer 22 of the first chip 10 in the connecting structure 33 corresponding to the second chip 20A and the size of the pad layer 22 of the first chip 10 in the connecting structures 33 corresponding to the second chip 20B, the pad layers 22 may vary in size. The same applies to the shape and material of the pad layer 22.

Moreover, in a comparison between the connecting structures 33 corresponding to the different second chips 20, combinations of a plurality of wiring layers 12 including the pad layers 22 forming the connecting structures 33 may vary among the connecting structures. Specifically, for example, in the first chip 10 in the example of FIG. 11A, a portion where the pad layers 22 forming the connecting structures 33 corresponding to the second chip 20A may have the structure of FIG. 2 described in the first embodiment, and a portion where the pad layers 22 forming the connecting structures 33 corresponding to the second chip 20B may have the structure of FIG. 10 described in the first embodiment. In this case, the pad layers 22 in the connecting structures 33 corresponding to the second chip 20A are formed in the first wiring layer 12A1 and the second wiring layer 12A2. A combination of the plurality of wiring layers 12 including the pad layers 22 forming the connecting structures 33 corresponding to the second chip 20A is the first wiring layer 12A1 and the second wiring layer 12A2. Moreover, the pad layers 22 in the connecting structures 33 corresponding to the second chip 20B are formed in the first wiring layer 12A1 and the third wiring layer 12A3. A combination of the plurality of wiring layers 12 including the pad layers 22 forming the connecting structures 33 corresponding to the second chip 20B is the first wiring layer 12A1 and the third wiring layer 12A3 and thus is different from the combination of the first wiring layer 12A1 and the second wiring layer 12A2.

### [2-2 Operation and Effect]

Even if pressures applied to the first chip 10 from the plurality of second chips 20 vary when each of the second chips 20 is crimped onto the first chip 10, the semiconductor device 1 according to the second embodiment can suppress faulty connections in the connecting structures 33 that electrically connect the bumps 25 of the second chips 20 and the pad layers 22 of the first chip 10.

### 3 Third Embodiment

### [3-1 Configuration of Semiconductor Device]

A semiconductor device 1 according to a third embodiment includes a plurality of pad layers 22 provided on a first chip 10 and a plurality of bumps 25 provided on a second chip 20 such that at least the pad layers 22 or the bumps 25 are irregular in size. Other configurations of the semiconductor device 1 according to the third embodiment may be formed like the semiconductor device 1 according to the first embodiment or the second embodiment. Thus, a description of other configurations is omitted.

### (Pad Layer)

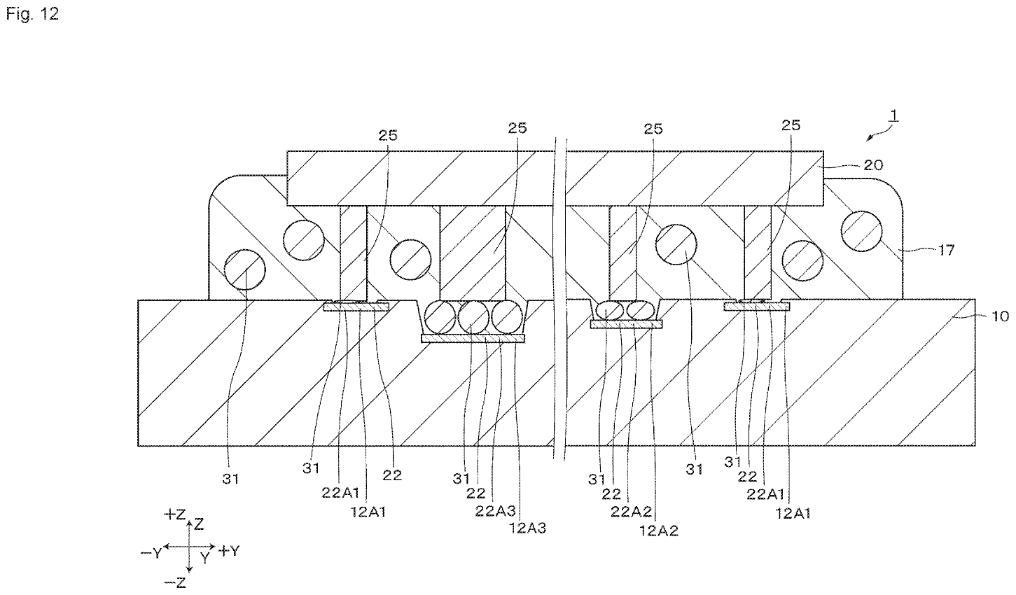

In the semiconductor device 1 according to the third embodiment, in a comparison between the sizes of the plurality of pad layers 22 formed in different wiring layers 12, the plurality of pad layers 22 of the first chip 10 may vary in size as illustrated in FIG. 12. The pad layers 22 may vary in size according to differences in bump size on the second chips 20. In the example of FIG. 12, the pad layers 22 vary in size according to differences among the wiring layers 12 forming the pad layers 22 and size differences of the bumps 25 on the second chip 20. Specifically, a third pad layer 22A3 has a larger size than a first pad layer 22A1 and a second pad layer 22A2. FIG. 12 is a bottom view for explaining an example of the second chip 20 in the semiconductor device 1 according to the third embodiment.

### (Bumps)

In the semiconductor device 1 according to the third embodiment, the plurality of bumps 25 formed on the second chip 20 may vary in size as illustrated in FIG. 12.

In the example of FIG. 12, as in the semiconductor device 1 according modification example 1 of the first embodiment, a first wiring layer 12A1, a second wiring layer 12A2, and a third wiring layer 12A3 sequentially include the pad layers 22 (the first pad layer 22A1, the second pad layer 22A2, and the third pad layer 22A3) from a first surface to a second surface. The pad layers 22 provided in the three wiring layers 12 are electrically connected to the bumps 25 of the second chip 20.

The bump 25 connected to the third pad layer 22A3 has a larger size than the bumps 25 connected to the first pad layer 22A1 and the second pad layer 22A2.

### (Thickness of Second Chip and Bump Size)

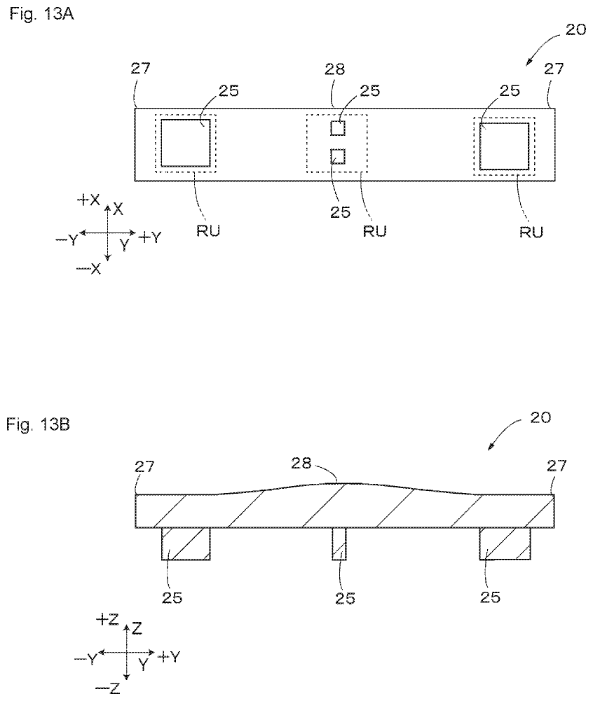

If the second chip has an uneven thickness, as illustrated in FIGS. 13A and 13B, the bumps 25 of the second chip 20 may vary in size according to the thickness of the second chip 20. In the example of FIG. 13A, a thickness of the second chip 20 near ends 27 of the second chip 20 is smaller than a thickness of the second chip 20 near a central portion 28 of the second chip 20. Furthermore, the bumps 25 formed near the ends 27 of the second chip are larger in size than the bumps 25 formed near the central portion 28 of the second chip 20. In this case, the area ratio of the bump 25 in a unit region RU determined near the ends 27 has a higher value than in the unit region RU determined in the central portion 28.

The plurality of pad layers 22 of the first chip 10 may vary in size according to the irregular sizes of the bumps 25 corresponding to differences in the thickness of the second chip 20.

### [3-2 Operation and Effect]

The semiconductor device 1 according to the third embodiment can obtain the same effect as the semiconductor device 1 according to the first embodiment.

### 4 Fourth Embodiment

### [4-1 Configuration of Semiconductor Device]

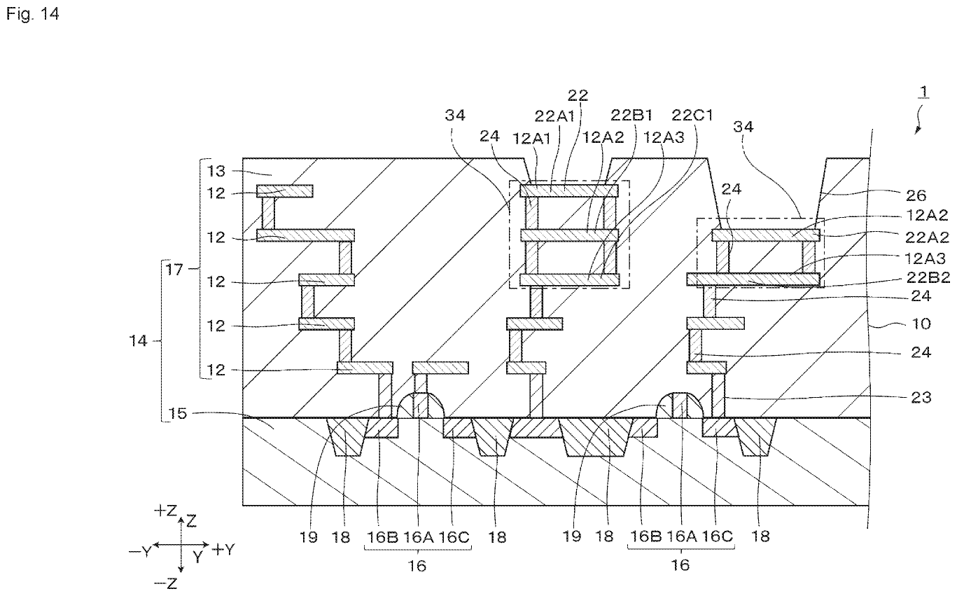

A semiconductor device 1 according to a fourth embodiment includes any one of the configurations of the first to third embodiments. Furthermore, as illustrated in FIG. 14, at least some of pad layers 22 are sequentially placed in the vertical direction with an insulating layer 13 interposed therebetween in the semiconductor device 1 according to the fourth embodiment. The pad layers 22 placed in the vertical direction form a pad structure 34 that electrically connects the pad layers 22. In FIG. 14, the pad structure 34 is illustrated as a portion surrounded by a chain line. FIG. 14 is a cross-sectional view for explaining an example of the semiconductor device according to the fourth embodiment. In the description of the fourth embodiment, a description of the same configurations as the semiconductor device 1 according to the first embodiment or the second embodiment is omitted. In FIG. 14, the illustration of an anisotropic conductive film 30 and a second chip 20 is omitted as in FIG. 10 for convenience of explanation.

### (Pad Structure)

In the semiconductor device 1 according to the fourth embodiment, for at least some of the pad layers 22 connected to bumps 25 of the second chip 20 to be connected, the pad layers 22 are further formed to be placed thereunder in the vertical direction. Thus, in a first chip 10, the pad layers 22 not facing the bumps 25 of the second chip 20 are formed under the pad layer 22 facing the bump 25 of the second chip 20.

In the example of FIG. 14, as the pad layers 22 facing the bumps 25 of the second chip 20, a first pad layer 22A1 formed in a first wiring layer 12A1 and a second pad layer 22A2 formed in a second wiring layer 12A2 are formed. Under the first pad layer 22A1, a pad layer 22B1 formed in the second wiring layer 12A2 and a pad layer 22C1 formed in a third wiring layer 12A3 are formed to be vertically placed as the pad layers 22 not facing the bumps 25. The first pad layer 22A1, the pad layer 22B1, and the pad layer 22C1 are electrically connected to one another by vias 24. In this case, the first pad layer 22A1, the pad layer 22B1, and the pad layer 22C1 electrically connected to one another by the vias 24 form the pad structure 34.

Moreover, under the second pad layer 22A2 formed in the second wiring layer 12A2, a pad layer 22B2 formed in the third wiring layer 12A3 is formed to be vertically placed as the pad layer 22 not facing the bump 25. The second pad layer 22A2 and the pad layer 22B2 are electrically connected to each other by the vias 24. In this case, the second pad layer 22A2 and the pad layer 22B2 electrically connected to each other by the vias 24 form the pad structure 34.

### [4-2 Operation and Effect]

The semiconductor device 1 according to the fourth embodiment can obtain the same effect as the semiconductor device according to the first embodiment. In the pad structure 34, the plurality of pad layers 22 form a hierarchical structure, so that the function of the pad layer 22 connected to the bump 25 can be performed as the overall pad structure 34 and the characteristics of the pad layer 22 serving as a connecting terminal can be stabilized.

### 5 Application Example

### (Electronic Device)

The semiconductor device according to the present disclosure may be provided for various electronic devices. For example, the semiconductor device 1 according to the embodiment (any one of the first to fourth embodiments) may be provided for various electronic devices. Particularly, the semiconductor device 1 according to the embodiment is preferably included in the electronic viewfinder of a video camera or a single-lens reflex camera or a head-mounted display or the like, which requires high resolution and is used for enlargement near eyes.

### Specific Example 1

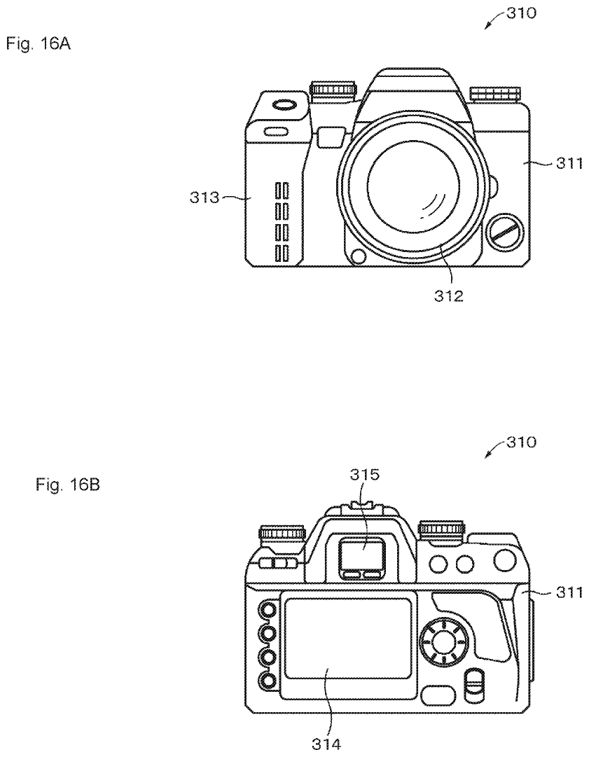

FIG. 16A is a front view illustrating an example of the appearance of a digital still camera 310. FIG. 16B is a rear view illustrating an example of the appearance of the digital still camera 310. The digital still camera 310 is an interchangeable single-lens reflex-type camera that has an interchangeable photographing lens unit (interchangeable lens) 312 substantially at the center of the front side of a camera main unit (camera body) 311 and has a grip portion 313 to be held by a photographer on the left side of the front side.

A monitor 314 is provided at a position shifted to the left from the center of the rear side of the camera main unit 311. On the monitor 314, an electronic viewfinder (eyepiece window) 315 is provided. Viewing through the electronic viewfinder 315 allows the photographer to visually recognize an optical subject image guided from the photographing lens unit 312 and determine the composition. The electronic viewfinder 315 may be any one of the semiconductor devices 1 according to the foregoing embodiment and modification examples.

### Specific Example 2

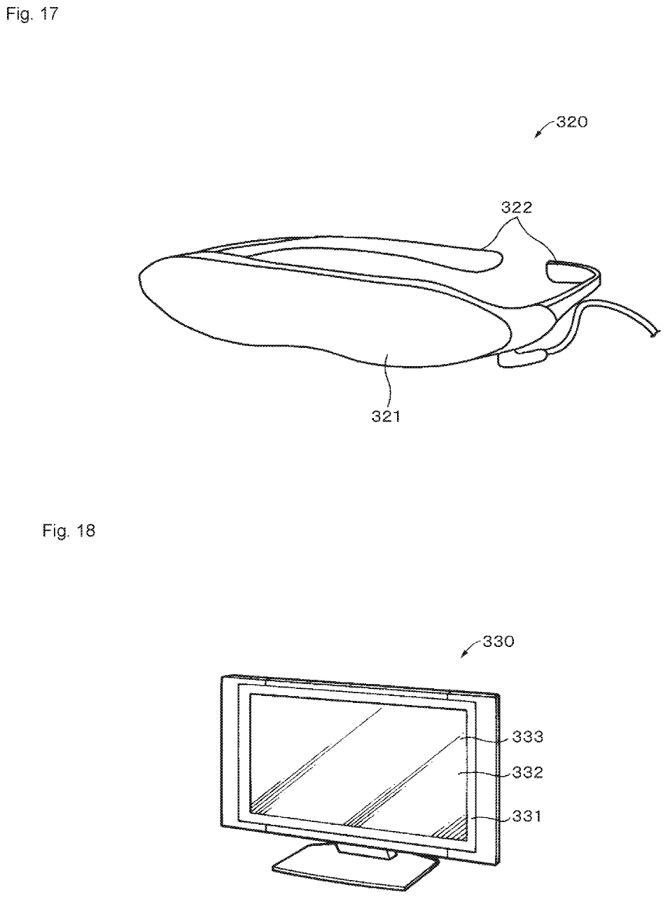

FIG. 17 is a perspective view illustrating an example of the appearance of a head-mounted display 320. The head-mounted display 320 has, for example, ear hooks 322 to be worn on the head of a user. The ear hooks 322 are provided on both sides of an eyeglass-shaped display unit 321. The display unit 321 may be any one of the semiconductor devices 1 according to the foregoing embodiment and modification examples.

### Specific Example 3

FIG. 18 is a perspective view illustrating an example of the appearance of a television set 330. The television set 330 has, for example, an image display screen part 331 including a front panel 332 and a filter glass 333. The image display screen part 331 is configured with any one of the semiconductor devices 1 according to the foregoing embodiment and modification examples.

### 6 Examples of Other Devices

In the first to fourth embodiments and the modification examples, examples of the semiconductor device used as a display device according to the present disclosure were specifically described. The semiconductor device according to the present disclosure is not limited to a display device and may be used as other devices. Examples of other devices include, for example, a logic device and an imaging device. Also, when the semiconductor device according to the present disclosure is used as a logic device or an imaging device, the configurations described in the first to fourth embodiments and the modification examples can be adopted.

However, if the semiconductor device 1 is a device other than a display device, the display part 11 of the first chip 10 is replaced with a part corresponding to the contents of the semiconductor device. For example, if the semiconductor device is an imaging device, an imaging part is formed instead of the display part 11 on the first chip 10. The imaging part can be formed by mounting an image sensor or the like on the first chip 10. The image sensor may be, for example, a CMOS image sensor. A CMOS image sensor is configured with, for example, multiple imaging elements arranged in a sensor region determined on a substrate, the imaging elements being electrically connected to a driving substrate. As in the description of the semiconductor device serving as a display device, the second chip 20 to be mounted is, for example, a chip where circuits (such as a driver IC) for controlling the imaging elements are mounted. For other configurations (for example, the positions of the pad layers 22), the contents described in the first to fourth embodiments are applicable.

The embodiments, the modification examples, and the example of the manufacturing method of the present disclosure have been described in detail. The present disclosure is not limited to the embodiments, the modification examples, and the example of the manufacturing method and can be modified in various ways on the basis of the technical spirit of the present disclosure.

For example, the configurations, methods, processes, shapes, materials, and numerical values in the foregoing embodiments, the modification examples, and the example of the manufacturing method are merely exemplary, and as necessary, different configurations, methods, processes, shapes, materials, and numerical values may be used.

The configurations, methods, processes, shapes, materials, and numerical values in the foregoing embodiments, the modification examples, and the example of the manufacturing method can be combined without departing from the gist of the present disclosure.

Unless otherwise specified, one of the materials exemplified in the foregoing embodiments can be used alone or two or more of the materials can be used in combination.

The contents of the present disclosure are not to be interpreted in a limited manner according to the exemplified advantageous effects of the present disclosure.

The present disclosure can be also configured as follows:

(1)

A semiconductor device including: a first chip that includes an insulating layer and a plurality of wiring layers having wires formed in the insulating layer; and at least one second chip that is mounted on the first chip and includes a plurality of conductive portions,
wherein the first chip includes a plurality of pad layers, and
connecting structures, each being formed to electrically connect the pad layer and the conductive portion,
the plurality of pad layers being formed at least in the plurality of different wiring layers.
   (2)

The semiconductor device according to (1), further including a resin film containing conductive particles between the first chip and the second chip, wherein the conductive portions are bumps, and the connecting structure has a structure that connects the pad layer and the bump via the conductive particles.

(3)

The semiconductor device according to (2), wherein a positional difference between the uppermost pad layer and the lowermost pad layer in a vertical direction is equal to or smaller than a half of the conductive particles.

(4)

The semiconductor device according to any one of (1) to (3), wherein the wiring layer not including the pad layer is absent between the plurality of wiring layers including the pad layers.

(5)

The semiconductor device according to any one of (1) to (3), wherein the wiring layer not including the pad layer is present between the plurality of wiring layers including the pad layers.

(6)

The semiconductor device according to any one of (1) to (5), wherein at least some of the pad layers are sequentially placed in the vertical direction with the insulating layer interposed between the pad layers, and the pad layers placed in the vertical direction form a pad structure that electrically connects the pad layers.

(7)

The semiconductor device according to any one of (1) to (6), wherein the plurality of pad layers formed in the different wiring layers vary in size.

(8)

The semiconductor device according to any one of (1) to (7), wherein the plurality of second chips are mounted on the first chip.

(9)

The semiconductor device according to (8), wherein the connecting structure is formed for each of the second chips, and
in a comparison between the connecting structures corresponding to the different second chips, the pad layers forming the connecting structures vary in size.
   (10)

The semiconductor device according to (8) or (9), wherein the connecting structure is formed for each of the second chips, and in a comparison between the connecting structures corresponding to the different second chips, combinations of the plurality of wiring layers including the pad layers forming the connecting structures vary among the connecting structures.

(11)

The semiconductor device according to any one of (1) to (10), wherein the second chip has an uneven thickness.

(12)

The semiconductor device according to (11), wherein the conductive portions are formed on the second chip such that a density of the conductive portions formed in a portion where the second chip has a relatively large thickness is lower than a density of the conductive portions formed in a portion where the second chip has a relatively small thickness.

(13)

The semiconductor device according to (11) or (12), wherein the conductive portion formed in a portion where the second chip has a relatively large thickness and the conductive portion formed in a portion where the second chip has a relatively small thickness are connected to the pad layers formed in the different wiring layers.

(14)

The semiconductor device according to (11) or (12), wherein the pad layer connected to the conductive portion formed in a portion where the second chip has a relatively small thickness is located higher than the pad layer connected to the conductive portion formed in a portion where the second chip has a relatively large thickness.

(15)

The semiconductor device according to any one of (1) to (14), wherein the first chip includes a silicon substrate, and the insulating layer and the wiring layer are provided on the silicon substrate.

(16)

The semiconductor device according to any one of (1) to (15), wherein the semiconductor device is used as a display device.

(17)

An electronic device including the semiconductor device according to any one of (1) to (16).

### REFERENCE SIGNS LIST

1 Semiconductor device
10 First chip
11 Display part
12 Wiring layer
13 Insulating layer
14 Driving substrate
15 Substrate
16 Semiconductor element
17 Multilayer wiring part
18 Element separating layer
19 Side-wall oxide film
20 Second chip
22 Pad layer
23 Contact wire
24 Via
25 Bump
26 Pad opening
27 End
28 Central portion
30 Anisotropic conductive film
31 Conductive particles
32 BG tape
33 Connecting structure
34 Pad structure
35 External connecting terminal
36 Suction part
37 Grinding part
113 Layer
120 Wire
125 Bump group
RU Unit region

1. A semiconductor device comprising: a first chip that includes an insulating layer and a plurality of wiring layers having wires formed in the insulating layer; and
at least one second chip that is mounted on the first chip and includes a plurality of conductive portions,
wherein the first chip includes a plurality of pad layers, and
connecting structures, each being formed to electrically connect the pad layer and the conductive portion,
the plurality of pad layers being formed at least in the plurality of different wiring layers.

2. The semiconductor device according to claim 1, further comprising a resin film containing conductive particles between the first chip and the second chip,
wherein the conductive portions are bumps, and
the connecting structure has a structure that connects the pad layer and the bump via the conductive particles.

3. The semiconductor device according to claim 2, wherein a positional difference between the uppermost pad layer and the lowermost pad layer in a vertical direction is equal to or smaller than a half of the conductive particles.

4. The semiconductor device according to claim 1, wherein the wiring layer not including the pad layer is absent between the plurality of wiring layers including the pad layers.

5. The semiconductor device according to claim 1, wherein the wiring layer not including the pad layer is present between the plurality of wiring layers including the pad layers.

6. The semiconductor device according to claim 1, wherein at least some of the pad layers are sequentially placed in the vertical direction with the insulating layer interposed between the pad layers, and the pad layers placed in the vertical direction form a pad structure that electrically connects the pad layers.

7. The semiconductor device according to claim 1, wherein the plurality of pad layers formed in the different wiring layers vary in size.

8. The semiconductor device according to claim 1, wherein the plurality of second chips are mounted on the first chip.

9. The semiconductor device according to claim 8, wherein the connecting structure is formed for each of the second chips, and
in a comparison between the connecting structures corresponding to the different second chips, the pad layers forming the connecting structures vary in size.

10. The semiconductor device according to claim 8, wherein the connecting structure is formed for each of the second chips, and
in a comparison between the connecting structures corresponding to the different second chips, combinations of the plurality of wiring layers including the pad layers forming the connecting structures vary among the connecting structures.

11. The semiconductor device according to claim 1, wherein the second chip has an uneven thickness.

12. The semiconductor device according to claim 11, wherein the conductive portions are formed on the second chip such that a density of the conductive portions formed in a portion where the second chip has a relatively large thickness is lower than a density of the conductive portions formed in a portion where the second chip has a relatively small thickness.

13. The semiconductor device according to claim 11, wherein the conductive portion formed in a portion where the second chip has a relatively large thickness and the conductive portion formed in a portion where the second chip has a relatively small thickness are connected to the pad layers formed in the different wiring layers.

14. The semiconductor device according to claim 11, wherein the pad layer connected to the conductive portion formed in a portion where the second chip has a relatively small thickness is located higher than the pad layer connected to the conductive portion formed in a portion where the second chip has a relatively large thickness.

15. The semiconductor device according to claim 1, wherein the first chip includes a silicon substrate, and the insulating layer and the wiring layer are provided on the silicon substrate.

16. The semiconductor device according to claim 1, wherein the semiconductor device is used as a display device.

17. An electronic device including the semiconductor device according to claim 1.
